(19) United States
(12) Patent Application Publication
(10) Pub. No.: US 2015/0055717 A1
(43) Pub. Date: Feb. 26, 2015

(54) RECEIVE ATTENUATION SYSTEM FOR TRAINLINE COMMUNICATION NETWORKS

(71) Applicants: Secure Communications Systems Inc., Santa Ana, CA (US); Electro-Motive Diesel, Inc., La Grange, IL (US)

(72) Inventors: Mark Alan FANARA, Blue Springs, MO (US); Neil Keith HABERMEHL, Irvine, CA (US)

(73) Assignees: Secure Communications Systems Inc., Santa Ana, CA (US); Electro-Motive Diesel, Inc., La Grange, IL (US)

(21) Appl. No.: 13/974,695

(22) Filed: Aug. 23, 2013

(51) Int. Cl. H04B 3/60; H03G 3/20

(52) U.S. Cl. CPC H04B 3/60; H03G 3/20
USPC 375/257

(57) ABSTRACT

A receive attenuation system for a trainline communication system utilizing an intra-consist electrical cable has an analog front end amplifier, a trainline communication processor, an adjustable attenuator, and a gain controller. The trainline communication processor is configured to generate a receive gain control signal configured to control receive gain of the analog front end amplifier. The adjustable attenuator is capable of being coupled to the intra-consist electrical cable and configured to variably attenuate signals received from the intra-consist electrical cable before transmitting the signals to the analog front end amplifier. The gain controller is coupled to the adjustable attenuator and configured to detect the receive gain control signal generated by the trainline communication processor, determine a supplemental attenuation control value based on the detected receive gain control signal, and control the adjustable attenuator according to the supplemental attenuation control signal.

### TECHNICAL FIELD

The present disclosure relates generally to a trainline communications network, and more particularly, to a receive attenuator for a trainline communication network.

### BACKGROUND

A consist includes one or more locomotives that are coupled together to produce motive power for a train of rail vehicles. The locomotives each include one or more engines, which combust fuel to produce mechanical power. The engine(s) of each locomotive can be supplied with liquid fuel (e.g., diesel fuel) from an onboard tank, gaseous fuel (e.g., natural gas) from a tender car, or a blend of the liquid and gaseous fuels. The mechanical power produced by the combustion process is directed through a generator and used to generate electricity. The electricity is then routed to traction motors of the locomotives, thereby generating torque that propels the train. The locomotives can be connected together at the front of the train or separated and located at different positions along the train. For example, the consist can be positioned at the front, middle, or end of the train. In some instances, more than one consist can be included within a single train. In some consists, the locomotives include computer systems for maintaining operations of the locomotive.

Because the locomotives of a consist must cooperate to propel the train, communication between the locomotives can be important. Historically, this communication has been facilitated through the use of an MU (Multi-Unit) cable that extends along the length of the consist. An MU cable is comprised of many different wires, each capable of carrying a discrete signal used to regulate a different aspect of consist operation. For example, a lead locomotive generates current within a particular one of the wires to indicate a power level setting requested by the train operator. When this wire is energized, the engines of all trailing locomotives are caused to operate at a specific throttle value. In another example, when one locomotive experiences a fault condition, another of the wires is energized to alert the other locomotives of the condition's existence.

In some consists, locomotives communicate via their respective computer systems on an Ethernet network formed over the MU cables, or other intra-consist electrical cables. With this configuration, network data can be transmitted from the computer system in the lead locomotive to the computer systems in the trail locomotives, and vice-versa. The network data includes data that is packaged as data packets and uniquely addressed to particular computer systems, or portions of the computer systems. The network data can be, for example, vehicle sensor data indicative of vehicle health, commodity condition data, temperature data, weight data, and security data. The network data is transmitted orthogonal to conventional non-network (i.e., command) data that is already being transmitted on the MU cable.

Traditionally, communication over a MU cable or other intra-locomotive cable was limited to voltage levels for individual wires within the MU cable. For example, a high voltage applied to an individual wire might indicate one value, while a low or zero voltage applied to the individual wire might indicate a second value. While MU cables provide an existing infrastructure that can be used by the computer systems of locomotives to communicate network data, MU cables were not designed for network data communication. For example, the wires within a MU cable are not shielded or twisted and are subject to interference. As a result, signal strength can degrade significantly as the signal propagates the length of a MU cable. For example, in a locomotive consist, the locomotive computer system adjacent to the signal's origin might receive the signal at 10 dBm, a locomotive further away in the consist might receive the signal at −30 dBm, which may be too weak to effectively transmit network data.

The signal degradation can be overcome by increasing strength of the signal when it is transmitted. While increasing the transmit signal allows for adequate signal strength to reach locomotive computer systems far away from the origin of the signal, it can overload the components of locomotive computer systems that are located close to the origin of the signal. For example, increasing the signal strength might produce a received 10 dBm signal at a locomotive further away from the origin of the signal, but might overload a locomotive computer system close to the origin of the signal with a 20 dBm signal.

Thus, one solution for overcoming signal degradation is to increase the strength of the transmit signal, but attenuate the signal on the receive end so as to not overload computer systems receiving the signal. Such a solution is described in U.S. Patent Publication No. 2012/0163201 (the '201 publication) filed by Williams et al. and published on Jun. 28, 2012. The '201 publication describes a cable modem auto-attenuation system capable of taking a high-power signal from the cable plant's service line, dropping the power value down to a usable level and transmitting the signal to a cable modem. Although the system of the '201 publication may minimally solve the problem of overcoming signal degradation over cable, the system would not be adequate for a trainline communications systems because it is not adapted to interface with trainline communication hardware and does not provide the granularity of attenuation control needed for trainline communication systems.

The disclosed system is directed to overcoming one or more of the problems set forth above.

### SUMMARY

In one aspect, the present disclosure is directed to a receive attenuation system for a trainline communication system utilizing intra-consist electrical cable. The system has an analog front end amplifier, a trainline communication processor, an adjustable attenuator, and a gain controller. The trainline communication processor is configured to generate a receive gain control signal configured to control receive gain of the analog front end amplifier. The adjustable attenuator is capable of being coupled to the intra-consist electrical cable and configured to variably attenuate signals received from the intra-consist electrical cable before transmitting the signals to the analog front end amplifier. The gain controller is coupled to the adjustable attenuator and configured to detect the receive gain control signal generated by the trainline communication processor, determine a supplemental attenuation control value based on the detected receive gain control signal, and control the adjustable attenuator according to the supplemental attenuation control signal.

In another aspect, the present disclosure is directed to a method of adjusting receive attenuation in a trainline communication system including detecting a receive gain control signal generated by a trainline communication processor, wherein the receive gain control signal is configured to control receive gain of an analog front end amplifier. The method further includes determining a supplemental attenuation control value based on the detected receive gain control signal, and controlling an adjustable attenuator according to the supplemental attenuation control signal. The adjustable attenuator is coupled to an intra-consist electrical cable and configured to variably attenuate signals received from the intra-consist electrical cable before transmitting the signals to the analog front end amplifier.

### BRIEF DESCRIPTION OF THE DRAWINGS

FIG. 1 is a pictorial illustration of an exemplary disclosed consist;

FIG. 2 is a diagrammatic illustration of an exemplary disclosed communication system that may be used in conjunction with the consist of FIG. 1;

FIG. 3 is a diagrammatic illustration of an exemplary system for receive attenuation for use with the communication system of FIG. 2; and

FIG. 4 is a flow chart illustrating an exemplary disclosed method for setting receive attenuation that can be performed by one or more components of FIG. 3.

### DETAILED DESCRIPTION

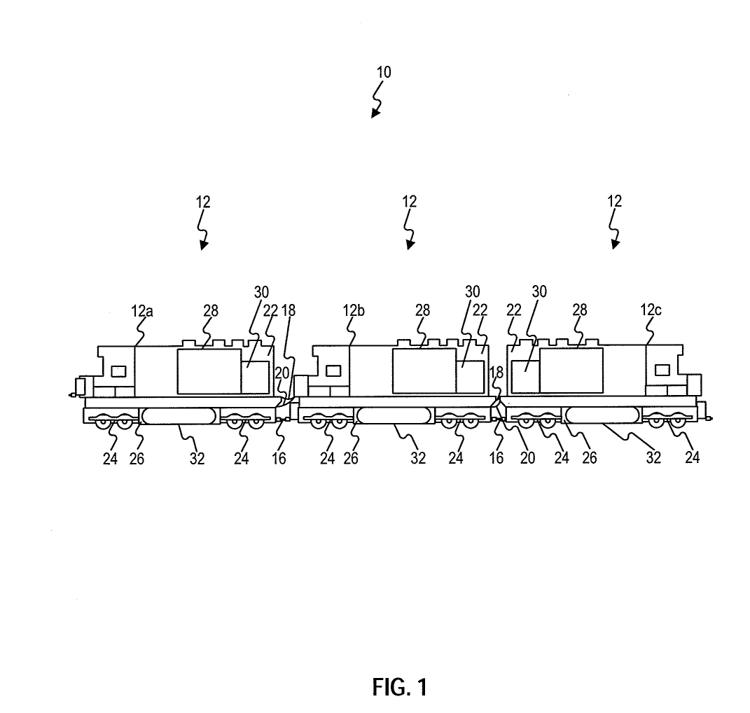

FIG. 1 illustrates an exemplary train consist 10 having one or more locomotives 12. In the disclosed embodiment, consist 10 has three different locomotives 12, including a lead locomotive 12a and two trailing locomotives 12b, 12c. It is contemplated, however, that consist 10 can include any number of locomotives 12 and other cars (e.g. tender cars), and that locomotives 12 can be located in any arrangement and in any orientation (e.g., forward-facing or rear-facing). Consist 10 can be located at the front of a train of other rail vehicles (not shown), within the train of rail vehicles, or at the end of the train of rail vehicles. It is also contemplated that more than one consist 10 can be included within a single train of rail vehicles, if desired, and/or that consist 10 can travel at times without a train of other rail vehicles.

Each locomotive 12 can be connected to an adjacent locomotive 12 in several different ways. For example, locomotives 12 can be connected to each other via a mechanical coupling 16, one or more fluid couplings 18, and one or more electrical couplings 20. Mechanical coupling 16 can be configured to transmit tractive and braking forces between locomotives 12. Fluid couplings 18 may be configured to transmit fluids (e.g., fuel, coolant, lubrication, pressurized air, etc.) between locomotives 12. Electrical couplings 20 can be configured to transmit power and/or data (e.g., data in the form of electrical signals) between locomotives 12. In one example, electrical couplings 20 include an intra-consist electrical cable, such as a MU cable, configured to transmit conventional command signals and/or electrical power. In another example, electrical couplings 20 include a dedicated data link configured to transmit packets of data (e.g., Ethernet data). In yet another example, the data packets can be transmitted via the intra-consist electrical cable. It is also contemplated that some data can be transmitted between locomotives 12 via a combination of the intra-consist electrical cable, the dedicated data link, and/or other means (e.g., wirelessly), if desired.

Each locomotive 12 can include a car body 22 supported at opposing ends by a plurality of trucks 24 (e.g., two trucks 24). Each truck 24 can be configured to engage a track (not shown) via a plurality of wheels, and to support a frame 26 of car body 22. Any number of engines 28 can be mounted to frame 26 within car body 22 and drivingly connected to a generator 30 to produce electricity that propels the wheels of each truck 24. Engines 28 can be internal combustion engines configured to combust a mixture of air and fuel. The fuel can include a liquid fuel (e.g., diesel) provided to engines 28 from a tank 32 located onboard each locomotive 12 or via fluid couplings 18, and/or a blended mixture of the liquid and gaseous fuels.

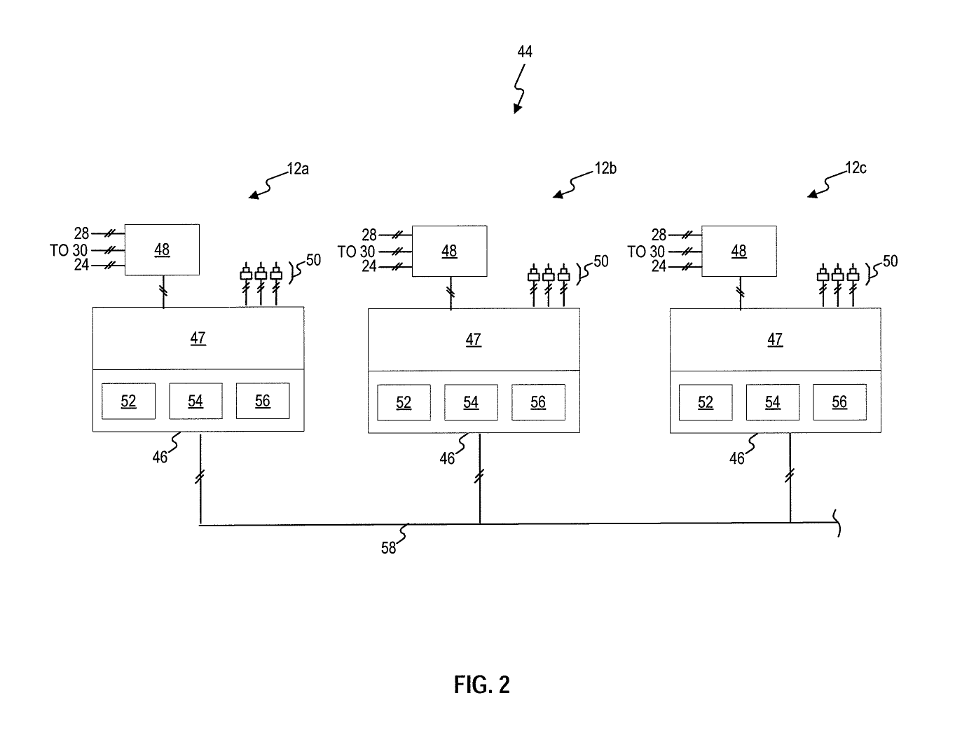

As shown in FIG. 2, consist 10 can be equipped with a communication system 44 that facilitates coordinated control of locomotives 12. Communication system 44 can include, among other things, an access point 46 for each locomotive 12. Each access point 46 can be connected to one or more wired and/or wireless networks, and used to communicate command signals and/or data between controllers 48 of each rail vehicle and various other network components 50 (e.g., sensor, valves, pumps, heat exchangers, accumulators, regulators, actuators, GPS components, etc.) that are used to control locomotives 12. Access points 46 can be connected to each other via electrical couplings 20 (e.g., via the intra-consist electrical cable, via the dedicated data link, and/or wirelessly). Access points 46 can be connected to a local area network hub (“LAN hub”) 47 that facilitates communication between the controllers 48, the network components 50, and access points 46.

Each access point 46 can include an inter-consist router (“IC router”) 52, an Ethernet bridge 54, and an MU modem 56, as well as conventional computing components known in the art (not shown) such as a processor, input/output (I/O) ports, a storage, a memory. The I/O ports may facilitate communication between the associated access point 46 and the LAN hub 47. In some embodiments, the I/O ports may facilitate communication between the associated access point 46 and one or more of network components 50.

Likewise, IC router 52 can facilitate communication between different access points 46 of locomotives 12 that are connected to each other via electrical couplings 20. In some embodiments, IC router 52 can provide a proxy IP address corresponding to controllers 48 and network components 50 of remote locomotives. For example, IC router 52 can provide a proxy IP address for one of network components 50 of locomotive 12b so controller 48 of locomotive 12a can communicate with it. The IC router 52 can include, or be connected to, an Ethernet bridge 54 that can be configured to translate network data to an electrical signal capable of being sent through intra-consist electrical cable 58. Ethernet bridge 54 can include or be connected to MU modem 56. MU modem 56 can be configured to modulate a carrier signal sent over intra-consist electrical cable 58 with the electrical signal received from Ethernet bridge 54 to transmit network data between access points 46. MU modem 56 can also be configured to demodulate signals received from access points 46 and send the demodulated signals to Ethernet bridge 54 for conversion to network data destined to controller 48 or network components 50. In some embodiments, MU modem 56 sends network data orthogonal to data traditionally transmitted over intra-consist electrical cable 58 (e.g., control data). Although FIG. 2 illustrates IC router 52, Ethernet bridge 54, and MU modem 56 as separate components, in some embodiments, one component can perform the functionality of two components. For example, Ethernet bridge 54 may perform the operations described above with respect to IC router 52, or Ethernet bridge 54 can include, or perform the operations of, MU modem 56.

In some embodiments, access point 46, IC router 52, Ethernet bridge 54, and/or MU modem 56 can include a processor, storage, and/or memory (not shown). The processor can include one or more processing devices, such as microprocessors and/or embedded controllers. The storage can include volatile or non-volatile, magnetic, semiconductor, tape, optical, removable, non-removable, or other type of computer-readable medium or computer-readable storage device. The storage can be configured to store programs and/or other information that can be used to implement one or more of the processes discussed below. The memory can include one or more storage devices configured to store information.

Each controller 48 can be configured to control operational aspects of its related rail vehicle. For example, controller 48 of lead locomotive 12a can be configured to control operational aspects of its corresponding engine 28, generator 30, traction motors, operator displays, and other associated components. Likewise, the controllers 48 of trail locomotives 12b and 12c can be configured to control operational aspects of their corresponding engines 28, generators 30, traction motors, operator displays, and other associated components. In some embodiments, controller 48 of lead locomotive can be further configured to control operational aspects of trail locomotives 12b and 12c, if desired. For example, controller 48 of lead locomotive 12a can send commands through its access point 46 to the access points of trail locomotives 12b and 12c.

Each controller 48 can embody a single microprocessor or multiple microprocessors that include a means for controlling an operation of the associated rail vehicle based on information obtained from any number of network components 50 and/or communications received via access points 46. Numerous commercially available microprocessors can be configured to perform the functions of controller 48. Controller 48 can include a memory, a secondary storage device, a processor, and any other components for running an application. Various other circuits may be associated with controller 48 such as power supply circuitry, signal conditioning circuitry, solenoid driver circuitry, and other types of circuitry.

The information obtained by a particular controller 48 via access points 46 and/or network components 50 can include performance related data associated with operations of each locomotive 12 (“operational information”). For example, the operational information can include engine related parameters (e.g., speeds, temperatures, pressures, flow rates, etc.), generator related parameters (e.g., speeds, temperatures, voltages, currents, etc.), operator related parameters (e.g., desired speeds, desired fuel settings, locations, destinations, braking, etc.), liquid fuel related parameters (e.g., temperatures, consumption rates, fuel levels, demand, etc.), gaseous fuel related parameters (e.g., temperatures, supply rates, fuel levels, etc.), and other parameters known in the art.

The information obtained by a particular controller 48 via access points 46 and/or network components 50 can also include identification data of the other rail vehicles within the same consist 10. For example, each controller 48 can include stored in its memory the identification of the particular rail vehicle with which controller 48 is associated. The identification data can include, among other things, a type of rail vehicle (e.g., make, model, and unique identification number), physical attributes of the associated rail vehicle (e.g., size, load limit, volume, power output, power requirements, fuel consumption rate, fuel supply capacity, etc.), and maintenance information (e.g., maintenance history, time until next scheduled maintenance, usage history, etc.). When coupled with other rail vehicles within a particular consist 10, each controller 48 can be configured to communicate the identification data to the other controllers 48 within the same consist 10. Each controller 48, can be configured to selectively affect operation of its own rail vehicle based on the obtained identification data associated with the other rail vehicles of consist 10.

In some embodiments, controllers 48 can be configured to affect operation of their associated rail vehicles based on the information obtained via access points 46 and/or network components 50 and one or more maps stored in memory. Each of these maps may include a collection of data in the form of tables, graphs, and/or equations. Controllers 48 can be configured to affect operation of their associated locomotives based on the position within a locomotive consist. The position of the locomotive associated with controller 48 can be used with the one or more maps to control the operation of the locomotive. For example, a map of throttle settings can be stored in the memory of controller 48. The map of throttle settings can include a mapping of consist position to throttle setting. For example, when the locomotive of controller 48 is the lead locomotive (e.g., in first position in the consist) the map may indicate that controller 48 should set the throttle to Notch 4, and when the locomotive of controller 48 is the third trailing locomotive (e.g., in fourth position in the consist), the map may indicate that controller 48 should set the throttle to Notch 2.

According to some embodiments, access point 46 can include one or more components for adjusting the attenuation of signals received on intra-consist electrical cable 58. Attenuation of signals received on intra-consist electrical cable 58 can be important to increase signal strength throughout communication system 44. For example, controller 48 of lead locomotive 12a may transmit a signal over intra-consist electrical cable 58 communicating network data. When the signal reaches access point 46 of locomotive 12b, it may be sufficiently strong to communicate the network data, but when the signal reaches access point 46 of locomotive 12c (which is further away), the signal may have degraded to an unacceptable level. To ensure that access point 46 of locomotive 12c receives sufficient signal, access port 46 of locomotive 12a can increase the signal strength of transmissions. In some embodiments, the increase in signal strength is global to all transmissions originating from access port 46 of locomotive 12a. As a result, while access point 46 of locomotive 12c receives a signal of sufficient strength, access port 46 of locomotive 12b receives a signal that is too strong, potentially degrading the signal's integrity and data throughout performance, resulting in reduced bandwidth or, in some cases, complete interruption of communication. By configuring the access points 46 of consist 10 to attenuate receive signals, access point 46 of locomotive 12a can send signals via intra-consist electrical cable 58 at a high signal level to accommodate access point 46 of locomotive 12c, while not overloading access point 46 of locomotive 12b because access point 46 of locomotive 12b can attenuate the signal before it reaches components that clip, distort, and degrade signals of high strength.

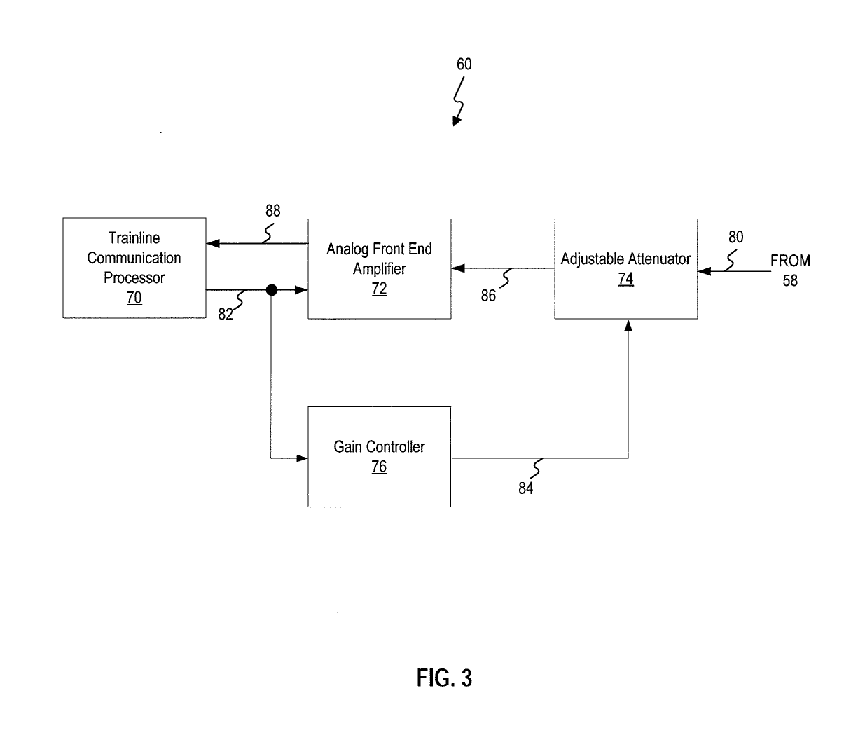

FIG. 3 is an illustration of an exemplary receive attenuation system 60 for use within communication system 44. According to some embodiments, receive attenuation system 60 operates to attenuate signals received by access point 46. Receive attenuation system 60 can include several components such as trainline communication processor 70, analog front end amplifier 72, adjustable attenuator 74, and gain controller 76. The components of receive attenuation system 60 can be connected by one or more signal paths that are configured to transmit digital or analog signals between the components of receive attenuation system 60. For example, receive attenuation system 60 can include MU receive signal path 80, receive gain control signal path 82, supplemental gain control signal path 84, attenuated receive signal path 86, and processor receive signal path 88. Receive attenuation system 60 can be disposed in, or be part of, access point 46 or one of the components of access point 46. For example, trainline communication processor 70 can be included in Ethernet bridge 54, or it can be a processor that is part of access point 46. In some embodiments, access point 46 can include a motherboard with one or more expansion slots for accepting daughtercards to enhance the functionality of access point 46, and the operation of one or more components of receive attenuation system 60 can be embodied on a daughtercard. For example, gain controller 76 and adjustable attenuator 74 can be embodied as daughtercards.

Trainline communication processor 70 can perform operations to enable access point 46 to perform network communications over intra-consist electrical cable 58. Trainline communication processor 70 can receive incoming signals via processor receive signal path 88. The incoming signals can include a modulated signal containing network data to be processed by trainline communication processor 70, or some other component of access point 46. Conventionally, analog front end amplifier 72 receives incoming signals on MU receive signal path 80 and amplifies or attenuates these signals before they are sent to trainline communication processor 70 on processor receive signal path 88. Trainline communication processor 70 can control the amplification or attenuation analog front end amplifier 72 provides by sending signals to it via receive gain control signal path 82. For example, when trainline communication processor 70 receives a signal on processor receive path 88 that is too strong, it can send a signal on receive gain control signal path 82 to request that analog front end amplifier 72 attenuate the signal on processor receive path 88. By way of further example, when trainline communication processor 70 receives a signal on processor receive path 88 that is too weak, it can send a signal on receive gain control signal path 82 to request that analog front end amplifier 72 amplify the signal on processor receive path 88.

In some conventional embodiments, while analog front end amplifier 72 can provide some attenuation of the signals received on processor receive path 88, the attenuation may not be sufficient in some consist communication systems. For example, in consists with a large number of locomotives, signal strength needs to be very high so that signals can traverse intra-consist electrical cables and still be of sufficient strength at either end of the consist. A conventional analog front end amplifier may not provide sufficient attenuation to accommodate the strength of the signal for access points of locomotives that are adjacent or close to each other within the consist. Also, in some conventional embodiments, analog front end amplifier 72 can be embodied within the same component as trainline communication processor 70 (e.g., Ethernet bridge 54), can be difficult or expensive to replace, or perform functions with legacy hardware that may make analog front end amplifier 72 impractical to replace.

Receive attenuation system 60 overcomes these problems of conventional embodiments by further including adjustable attenuator 74. As shown in FIG. 3, adjustable attenuator 74 can be inserted between the analog front end amplifier 72 and intra-consist electrical cable 58. Adjustable attenuator 74 can be configured to receive incoming signals on MU receive signal path 80, attenuate the incoming signals, and send the attenuated incoming signals to analog front end amplifier 72, thereby providing extra attenuation for incoming signals. Adjustable attenuator 74 can include circuitry that is capable of variably attenuating a signal. In some embodiments, adjustable attenuator 74 includes inputs allowing for external control. Adjustable attenuator 74 can be controlled digitally (e.g., by receiving a bit stream of data corresponding to the attenuation level to apply), and/or it can be controlled with an analog signal (e.g., a voltage or current corresponding to the attenuation level to apply). Because receive attenuation system 60 provides multiple levels of attenuation, e.g., one using adjustable attenuator 74 and another using analog front end amplifier 72, it can provide finer tuned attenuation than that of conventional embodiments.

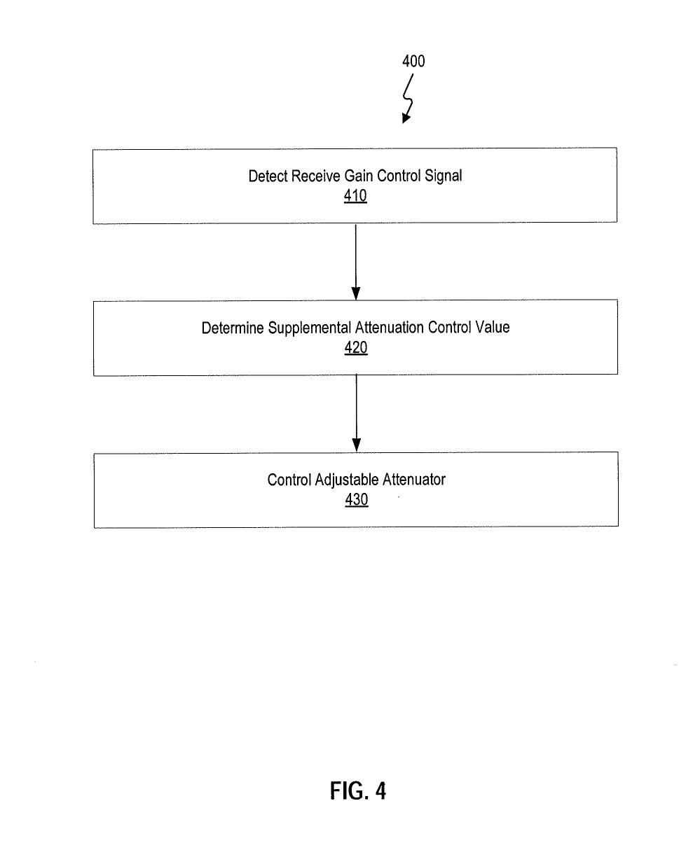

In some embodiments, adjustable attenuator 74 can be controlled by gain controller 76. Gain controller 76 can be connected to receive gain control signal path 82 to detect receive gain control signals sent by trainline communication processor 70 to analog front end amplifier 72. Based on the detected receive gain control signals, gain controller 76 can determine a supplemental attenuation control value. The supplemental attenuation control value can be encoded in a signal that is sent over supplemental attenuation control signal path 84 to adjustable attenuator 74. Further operations of gain control 76 are described in greater detail below with respect to FIG. 4.

### INDUSTRIAL APPLICABILITY

The disclosed receive attenuation system can be applicable to any consist that includes a plurality of rail cars, such as locomotives. The disclosed receive attenuation system can provide finer granularity of attenuation control than what can be achieved using attenuators currently available in trainline communication analog front end amplifiers. The operation of the receive attenuation system will now be explained.

FIG. 4 is a flowchart illustrating an exemplary disclosed method for setting receive attenuation that can be performed by one of the components illustrated in FIG. 3. During the operation of consist 10, gain controller 76 can perform method 400 to adjust receive attenuation using the adjustable attenuator 74. Although the description that follows describes method 400 as being performed by gain controller 76, other components of access point 46 can perform one or more of the steps of method 400 in some embodiments.

Gain controller 76 begins method 400 by detecting a receive gain control signal (step 410). As described above, gain controller 76 can be connected to receive gain control path 82 that trainline communication processor 70 uses to send a receive gain control signal to analog front end amplifier 72. The receive gain control signal can be, in some embodiments, a digital control signal that specifies to analog front end amplifier 72 the amount of signal attenuation to apply to the data signal that the analog front end amplifier 72 sends to the trainline communication processor 70 via receive signal path 86. For example, the receive gain control signal can be a 5-bit digital signal from 00000 to 11111. When the receive gain control signal is 00000 the trainline communication processor 70 can command the analog front end amplifier 72 to provide maximum attenuation, and when the receive gain control signal 82 is 11111, the trainline communication processor 70 can command the analog front end amplifier 72 to provide no attenuation. Receive gain control signals between 00000 and 11111 command the analog front end amplifier 72 to provide attenuation somewhere between zero and the maximum attenuation. In some embodiments, the receive gain control signal can be an analog signal that has a variable voltage. When the voltage is low the trainline communication processor 70 commands the analog front end amplifier 72 to provide maximum attenuation, and when the voltage is high the trainline communication processor 70 commands the analog front end amplifier 72 to provide minimum, or zero attenuation. Gain controller 76 can be configured to detect the receive gain control signal, whether digital or analog, to determine whether to control adjustable attenuator 74 to provide supplemental attenuation.

Based on the detected receive gain control signal, gain controller 76 determines a supplemental attenuation control value (step 420). According to some embodiments, the supplemental attenuation control value is proportionate with the detected receive gain control signal. For example, the receive gain control signal can be a 5-bit digital signal ranging from 00000 to 11111 providing sixteen possible supplemental attenuation control values, including zero. When gain controller 76 detects a receive gain control signal of 11000, it can determine a supplemental attenuation control value that provides 24/31 of the maximum attenuation available with adjustable attenuator 74. In some embodiments, gain controller 76 can access a data structure or configuration file that specifies the supplemental attenuation control value to use for detected gain control signals. For example, gain controller 76 can access a data structure or configuration file with the data listed below to determine the supplemental attenuation control value for an adjustable attenuator that can be controlled using voltage:

| Detected Receive | Supplemental Attenuation |
|---|---|
| Gain Control Signal | Control Value |
| 00000 | 0 V |
| 00001 | 0 V |
| 00010 | 0.5 V |
| 00011 | 0.5 V |
| 00100 | 0.5 V |
| 00101 | 0.5 V |
| 00110 | 0.5 V |
| 00111 | 0.5 V |
| 01000 | 1.0 V |
| 01001 | 1.0 V |
| 01010 | 1.0 V |
| 01011 | 1.0 V |
| 01100 | 1.0 V |
| 01101 | 1.0 V |
| 01110 | 1.0 V |
| 01111 | 1.0 V |
| 10000 | 1.5 V |
| 10001 | 1.5 V |
| 10010 | 1.5 V |
| 10011 | 1.5 V |
| 10100 | 1.5 V |
| 10101 | 1.5 V |
| 10110 | 1.5 V |
| 10111 | 1.5 V |
| 11000 | 2.0 V |
| 11001 | 2.0 V |
| 11010 | 2.0 V |
| 11011 | 2.0 V |
| 11100 | 2.0 V |
| 11101 | 2.0 V |
| 11110 | 3.0 V |
| 11111 | 3.0 V |

As shown in the table above, the use of a configuration file allows gain controller 76 to determine the supplemental attenuation control value according to a step function, if desired. In some embodiments, gain controller 76 can also use a programmatically set function to calculate a supplemental attenuation control value for a detected receive gain control value.

After gain controller 76 determines the supplemental attenuation control value, it can control adjustable attenuator 74 using it (step 430). As described above, gain controller 76 can send the supplemental control value using supplemental gain control signal path 84. Once gain controller 76 controls adjustable attenuator 74, adjustable attenuator 74 attenuates signals received on MU receive signal path 80 before the signals are sent to analog front end amplifier 72.

Several advantages over the prior art may be associated with the receive attenuation system. The disclosed receive attenuation system can provide finer granularity of attenuation control than what can be achieved using attenuators currently available in trainline communication analog front end amplifiers. In addition, when implemented using daughtercards, the disclosed receive attenuation system can be easily integrate with existing trainline communication systems, including existing Ethernet bridges and/or access points.

It will be apparent to those skilled in the art that various modifications and variations can be made to the receive attenuation system. Other embodiments will be apparent to those skilled in the art from consideration of the specification and practice of the disclosed receive attenuation system. It is intended that the specification and examples be considered as exemplary only, with a true scope being indicated by the following claims and their equivalents.

What is claimed is:

1. A receive attenuation system for a trainline communication system utilizing an intra-consist electrical cable, the system comprising:
an analog front end amplifier;
a trainline communication processor configured to generate a receive gain control signal configured to control receive gain of the analog front end amplifier;
an adjustable attenuator capable of being coupled to the intra-consist electrical cable and configured to variably attenuate signals received from the intra-consist electrical cable before transmitting the signals to the analog front end amplifier; and,
a gain controller coupled to the adjustable attenuator and configured to:
detect the receive gain control signal generated by the trainline communication processor,
determine a supplemental attenuation control value based on the detected receive gain control signal, and
control the adjustable attenuator according to the supplemental attenuation control signal.

2. The receive attenuation system of claim 1, wherein the analog front end amplifier is configured to further attenuate the signal transmitted from the adjustable attenuator.

3. The receive attenuation system of claim 1, wherein the adjustable attenuator is a daughtercard.

4. The receive attenuation system of claim 1, wherein the gain controller is a daughtercard.

5. The receive attenuation system of claim 1, wherein the receive gain control signal includes a five bit digital signal.

6. The receive attenuation system of claim 1, wherein the trainline communication processor is part of an Ethernet bridge for the trainline communication system.

7. The receive attenuation system of claim 6, wherein the analog front end amplifier is part of the Ethernet bridge for the trainline communication system.

8. The receive attenuation system of claim 1, wherein the supplemental attenuation control value is determined based on data stored in a configuration file.

9. The receive attenuation system of claim 1, wherein the gain controller controls the adjustable attenuator using a digital command.

10. The receive attenuation system of claim 1, wherein the gain controller controls the adjustable attenuator using an analog signal.

11. A method of adjusting receive attenuation in a trainline communication system, the method comprising:
detecting a receive gain control signal generated by a trainline communication processor, wherein the receive gain control signal is configured to control receive gain of an analog front end amplifier;
determining a supplemental attenuation control value based on the detected receive gain control signal, and
controlling an adjustable attenuator according to the supplemental attenuation control signal, the adjustable attenuator coupled to an intra-consist electrical cable and configured to variably attenuate signals received from the intra-consist electrical cable before transmitting the signals to the analog front end amplifier.

12. The method of claim 11, wherein the method is performed by a gain controller including a daughtercard.

13. The method of claim 11, wherein the receive gain control signal includes a five bit digital signal.

14. The method of claim 11, wherein controlling the adjustable attenuator includes controlling the adjustable attenuator using a digital command.

15. The method of claim 11, wherein controlling the adjustable attenuator includes controlling the adjustable attenuator using an analog signal.

16. A locomotive consist comprising:
an intra-consist electrical cable;
a first locomotive having a first access point configured to transmit signals via the intra-consist electrical cable;
a second locomotive having a second access point including:
an Ethernet bridge including a trainline communication processor configured to generate receive gain control signals;
an analog front end amplifier coupled to the Ethernet bridge and configured to receive the gain control signals from the trainline communication processor;
an adjustable attenuator coupled to the intra-consist electrical cable and the analog front end amplifier, the adjustable attenuator configured to variably attenuate the signals received from the first access point via the intra-consist electrical cable before transmitting the received signals to the analog front end amplifier; and
a gain controller coupled to the adjustable attenuator configured to:
detect the receive gain control signals generated by the trainline communication processor,
determine a supplemental attenuation control value based on the detected receive gain control signal, and
control the adjustable attenuator according to the supplemental attenuation control signal.

17. The locomotive consist of claim 16 wherein the gain controller and the adjustable attenuator constitute on one or more daughtercards.

18. The locomotive consist of claim 16 wherein the receive gain control signal includes a five bit digital signal.

19. The locomotive consist of claim 16 wherein the adjustable attenuator is controlled using a digital command.

20. The locomotive consist of claim 16 wherein the adjustable attenuator is controlled using an analog signal.
